(19) United States
(12) Patent Application Publication
(10) Pub. No.: US 2025/0215556 A1
(43) Pub. Date: Jul. 3, 2025

(54) METHOD FOR FORMING HYDROGEN-CONTAINING CARBON FILM USING PECVD

(71) Applicant: TES Co., Ltd, Yongin-si (KR)

(72) Inventors: Sungwoo LEE, Yongin-si (KR); In Gyu CHOI, Yongin-si (KR)

(73) Assignee: TES Co., Ltd, Yongin-si (KR)

(21) Appl. No.: 19/002,207

(22) Filed: Dec. 26, 2024

(30) Foreign Application Priority Data
Dec. 27, 2023 (KR) 10-2023-0193359

(51) Int. Cl. C23C 16/22; C23C 16/505; C23C 16/56

(52) U.S. Cl. CPC C23C 16/22; C23C 16/505; C23C 16/56

(57) ABSTRACT

Disclosed is a method for forming a carbon film having a high hydrogen content. The method for forming the hydrogen-containing carbon film includes loading a substrate into a chamber; supplying a carbon precursor into the chamber; raising a temperature of the substrate to a predetermined temperature; and discharging the carbon precursor in the chamber to deposit a carbon film on the substrate, wherein the carbon precursor is one type of a compound including carbon and hydrogen and having 3 or more carbon atoms, wherein a content of hydrogen contained in the deposited carbon film is about 40 atomic percent or higher.

### CROSS-REFERENCE TO RELATED APPLICATION

This application claims priority from Korean Patent Application No. 10-2023-0193359 filed on Dec. 27, 2023, in the Korean Intellectual Property Office, and all the benefits accruing therefrom under 35 U.S.C. 119, the contents of which in its entirety are herein incorporated by reference.

### BACKGROUND

The present disclosure relates to a method for forming a carbon film using a PECVD scheme. More specifically, the present disclosure relates to a method for forming a carbon film having a high hydrogen content by controlling a carbon precursor, a deposition temperature, RF power, etc. when depositing the carbon film using the PECVD scheme.

In addition, the present disclosure relates to a method for forming a hydrogen-containing carbon film having a high hydrogen content and excellent adhesion to a photoresist pattern.

Today, in a semiconductor manufacturing process, a finer and thinner pattern is required. In order to meet this requirement, a so-called extreme ultraviolet (EUV) process has been developed. The extreme ultraviolet process uses a wavelength that is shorter by at least 10 times than that used in a conventional deep ultraviolet process, so that a finer and thinner pattern may be formed on the substrate.

However, when the photoresist pattern is formed on the substrate in the extreme ultraviolet process, the pattern may collapse, or the photoresist pattern may not be cured properly. It is known that this is because the sensitivity of the photoresist to extreme ultraviolet rays is not high.

To this end, a scheme of forming an auxiliary layer under the photoresist pattern has been proposed.

FIG. 1 schematically shows an example in which the auxiliary layer and the photoresist pattern are formed on the substrate for the extreme ultraviolet process.

Referring to FIG. 1, an auxiliary layer 110 is formed on a substrate 101, and a photoresist pattern 120 is formed thereon.

The auxiliary layer 110 may be formed by spin-coating a composition including a metal, a metal halide, a metal carbide, a metal sulfide, a metal nitride, a metal oxide, a crosslinking agent, etc., and then baking the coated composition. However, in this scheme, the spin coating and baking processes are required, there is a disadvantage in that a process time is increased.

In order to solve this disadvantage, many studies have recently been conducted to utilize a carbon film as the photoresist auxiliary layer 110. When forming the carbon film as the photoresist auxiliary layer, it is important to have a high hydrogen content in the carbon film.

To this end, a scheme of increasing a hydrogen content in the carbon film by supplying a hydrogen gas (H₂) together with a carbon precursor such as C₂H₂ is known. However, in this approach, a separate device is required to supply C₂H₂ into the chamber, and an amount of hydrogen contained in the deposited carbon film is not constant based on a flow rate of the hydrogen gas, thus making the process difficult.

### SUMMARY

A purpose of the present disclosure is to provide a method for forming a hydrogen-containing carbon film using a PECVD scheme capable of increasing the hydrogen content in the carbon film while using a single carbon precursor that does not contain hydrogen gas.

In addition, a purpose of the present disclosure is to provide a carbon film deposition method using a PECVD scheme such that the carbon film has a high hydrogen content and excellent adhesion to a photoresist pattern.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

In order to achieve the purposes, a first aspect of the present disclosure provides a method for forming a hydrogen-containing carbon film, the method comprising: loading a substrate into a chamber; supplying a carbon precursor into the chamber; raising a temperature of the substrate to a predetermined temperature; and discharging the carbon precursor in the chamber to deposit a carbon film on the substrate, wherein the carbon precursor is one type of a compound including carbon and hydrogen and having 3 or more carbon atoms, wherein a content of hydrogen contained in the deposited carbon film is about 40 atomic percent or higher.

In accordance with some embodiments of the method for forming the hydrogen-containing carbon film, the carbon precursor is C₃H₆.

In accordance with some embodiments of the method for forming the hydrogen-containing carbon film, the carbon precursor is C₆H₁₂.

In accordance with some embodiments of the method for forming the hydrogen-containing carbon film, the carbon precursor together with a carrier gas are supplied into the chamber.

In accordance with some embodiments of the method for forming the hydrogen-containing carbon film, the deposition of the carbon film is performed at a substrate temperature of about 100 to 300° C.

In accordance with some embodiments of the method for forming the hydrogen-containing carbon film, the deposition of the carbon film is performed at a substrate temperature of about 180 to 220° C.

In accordance with some embodiments of the method for forming the hydrogen-containing carbon film, the deposition of the carbon film is performed at a RF power of about 300 to 600 W.

In accordance with some embodiments of the method for forming the hydrogen-containing carbon film, the deposition of the carbon film is performed at a RF power of about 350 to 450 W.

In order to achieve the purposes, a first aspect of the present disclosure provides a method for forming a hydrogen-containing carbon film, the method comprising: depositing a carbon film using a single type of a carbon precursor including carbon and hydrogen and having at least 3 carbon atoms in a PECVD process such that the deposited carbon film has a hydrogen content in a range of about 40 atomic % or greater; and performing a post-plasma treatment on the deposited carbon film.

In accordance with some embodiments of the method for forming the hydrogen-containing carbon film, the post-plasma treatment is performed using hydrogen plasma or NF₃ plasma.

In accordance with some embodiments of the method for forming the hydrogen-containing carbon film, each of the deposition of the carbon film and the post-plasma treatment is performed in an in-situ manner.

According to the method for depositing the hydrogen-containing carbon film according to the present disclosure, the deposited carbon film may have the high hydrogen content while using a single carbon precursor.

In addition, the hydrogen-containing carbon film having high adhesion to the photoresist pattern can be formed by performing the post-plasma treatment on the deposited carbon film.

When the auxiliary layer is formed using the conventional spin coating method, many subsequent processes are required to adjust the thickness and compositions of the auxiliary layer. However, when the auxiliary layer is formed in the PECVD scheme according to the present disclosure, the thickness in a range of about 5 to 10 nm of the thin film including hydrogen may be obtained, and the composition of the thin film including hydrogen may be easily controlled. Further, subsequent processes may not be required compared to the case using the spin coating method, such that the process time may be reduced.

Therefore, the hydrogen-containing carbon film formed using the method according to the present disclosure has a high hydrogen content and a large contact angle, and thus is suitable for use as the auxiliary layer under the photoresist for an extreme ultraviolet process.

The effects of the present disclosure are not limited to the above-mentioned effects, and other effects as not mentioned will be clearly understood by those skilled in the art from the following detailed description.

### BRIEF DESCRIPTION OF DRAWINGS

FIG. 1 schematically illustrates an example in which an auxiliary layer and a photoresist pattern are formed on a substrate for an extreme ultraviolet (EUV) process.

FIG. 2 is a flowchart schematically showing a method for forming a hydrogen-containing carbon film according to the present disclosure.

FIG. 3 schematically shows an example of a PECVD apparatus that may be used in a method for forming a hydrogen-containing carbon film according to the present disclosure.

FIG. 4 is a graph showing a hydrogen content of a deposited carbon film based on a deposition source and a deposition temperature.

FIG. 5 is a graph showing a correlation between a FTIR result and the content of hydrogen in the carbon film.

FIG. 6 shows the hydrogen content of the carbon film formed from C₃H₆ based on a substrate temperature.

FIG. 7 shows the hydrogen content of the carbon film formed from C₃H₆ at about 200° C. based on RF power.

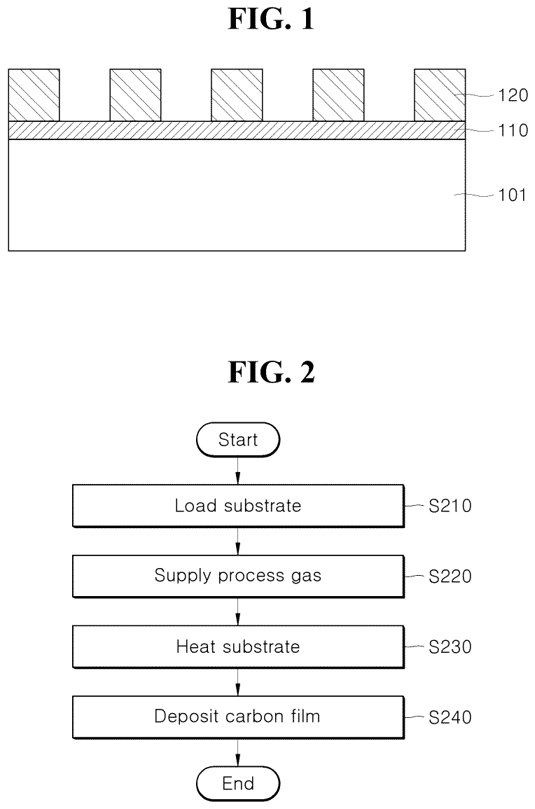

### REFERENCE NUMERALS

1: PECVD apparatus
2: Chamber
3: Showerhead
4: Susceptor
5: RF power
6: First electrode
7: RF Filter
8: Ground Line
101: Substrate
110: Auxiliary layer
120: Photoresist pattern

### DETAILED DESCRIPTIONS

Hereinafter, a preferred embodiment of the present disclosure will be described in detail with reference to the accompanying drawings. Advantages and features of the present disclosure, and a method of achieving the advantages and features will become apparent with reference to embodiments described below in detail together with the accompanying drawings. However, the present disclosure is not limited to the embodiments as disclosed below, but may be implemented in various different forms. Thus, these embodiments are set forth only to make the present disclosure complete, and to entirely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items.

Expressions such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when a first element or layer is referred to as being “connected to”, or “coupled to” a second element or layer, the first element may be directly connected to or coupled to the second element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present therebetween.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating embodiments.

Further, as used herein, when a layer, film, area, plate, or the like is disposed “on” or “on a top” of another layer, film, area, plate, or the like, the former may directly contact the latter or still another layer, film, area, plate, or the like may be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former may directly contact the latter or still another layer, film, area, plate, or the like may be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

Further, in a specific case, a term may be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Descriptions.

Hereinafter, a method for forming a hydrogen-containing carbon film using a PECVD scheme according to a preferred embodiment of the present disclosure will be described in detail with reference to the accompanying drawings.

FIG. 2 is a flowchart schematically showing a method for forming a hydrogen-containing carbon film according to the present disclosure.

Referring to FIG. 2, the method of forming the hydrogen-containing carbon film according to the present disclosure includes a substrate loading step S210, a process gas supply step S220, a substrate heating step S230, and a carbon film deposition step S240. In this regard, the substrate heating step S230 may be started after the process gas supply step S220 has been started. In another example, the process gas supply step S220 and the substrate heating step S230 may be simultaneously started. In still another example, after the substrate heating step S230 has been started, the process gas supply step S220 may be started.

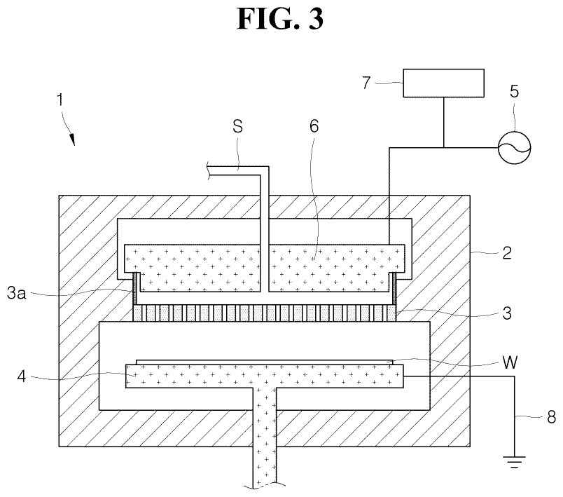

In the substrate loading step S210, the substrate is loaded into the chamber. Specifically, the substrate is loaded on the susceptor (4 in FIG. 3) in the chamber. The substrate on which the carbon film is to be deposited may be a circular wafer or a quadrangular wafer. predetermined pattern may be formed on the substrate.

In addition, the substrate SUB may be a substrate on which a hard mask HM has been formed. The hard mask may be an amorphous carbon film. In this case, the carbon film formed using the method according to the present disclosure may be formed on the amorphous carbon film.

After loading the substrate, an inner space of the chamber is evacuated using an external vacuum system (not shown).

Subsequently, in the process gas supply step S220, a carbon precursor as a process gas is supplied into the chamber.

Subsequently, in the substrate heating step S230, the substrate temperature is raised to a predetermined temperature.

Subsequently, in the carbon film deposition step S240, the carbon precursor in the chamber is discharged such that a hydrogen-containing carbon film is deposited on the substrate.

After the deposition of the carbon film, a step of purging the inner space of the chamber with nitrogen gas or the like may be performed.

FIG. 3 schematically shows an example of a PECVD apparatus that may be used in the method for forming the hydrogen-containing carbon film according to the present disclosure.

Referring to FIG. 3, the illustrated PECVD apparatus 1 includes a gas supply line S, a chamber 2, a showerhead 3, a susceptor 4, a RF power supply 5, and a first electrode 6.

The gas supply line S is connected to the chamber 2 and serves to supply a process gas outside the chamber 2 into the chamber 2. In accordance with the present disclosure, the process gas may be a carbon precursor, and in particular, may be a single carbon compound containing carbon and hydrogen. The process gas may include a carrier gas for the carbon compound.

In one example, when the carbon precursor is liquid at room temperature and is, for example, C₆H₁₂, the liquid carbon precursor may be vaporized through a vaporizer and then supplied into the chamber. Alternatively, when the carbon precursor is in a gaseous state at room temperature and is, for example, C₃H₆, the gaseous carbon precursor may be directly supplied into the chamber without heating thereof.

The carbon precursor may be independently supplied into the chamber without the carrier gas. Alternatively, the carbon precursor together with an inert gas such as argon gas, helium gas, nitrogen gas, or the like acing as a carrier gas may be supplied into the chamber.

The showerhead 3 is provided at an upper side of the inner space of the chamber 2 and sprays the process gas injected through the gas supply line S into the chamber.

The susceptor 4 on which the substrate W such as a wafer has been loaded (supported) is provided at a lower side of the inner space of the chamber 2. The susceptor 4 may be provided with a temperature control means for raising/cooling the substrate. In addition, the susceptor 4 may function as a ground electrode, as shown in FIG. 3. A separate ground line 8 may be provided to further improve grounding performance. Although not shown, a high frequency power source or an DC power source may be connected to the susceptor 4 which thus may act as a second electrode (bias electrode).

The first electrode 6 is electrically connected to the RF power source 5 and is used as an electrode for plasma discharge in the chamber 2. In the example shown in FIG. 3, the showerhead 3 is electrically connected to the first electrode 6 by a connector 3a so that a combination of the first electrode 6 and the showerhead 3 functions as a single electrode. Accordingly, the RF power generated by the RF power source 5 is filtered through an RF filter 7 and applied to the inner space of the process chamber 2 through the first electrode 6 and the showerhead 3. In accordance with the present disclosure, the RF power supply 5 generates RF power of about 600 W or lower, preferably about 300 to 600 W.

In addition to using the PECVD apparatus as illustrated in FIG. 3, various known PECVD apparatuses may be used in the method for forming the hydrogen-containing carbon film according to the present disclosure.

In accordance with the present disclosure, the carbon precursor is one type of a compound containing carbon and hydrogen and having 3 or more carbon atoms. For example, the carbon precursor may be C₃H₆. In another example, the carbon precursor may be C₆H₁₂. As a result of using this carbon precursor and controlling the substrate temperature and the RF power, the content of hydrogen contained in the deposited carbon film was 40 atomic % or higher. This value corresponds to a higher hydrogen content than that in the hydrogen-containing carbon film formed by using C₂H₂ alone or by supplying H₂ together with C₂H₂.

The deposition of the carbon film may be performed at a substrate temperature of about 100 to 300° C. More preferably, the deposition of the carbon film may be performed at a substrate temperature of about 180 to 220° C. When the deposition temperature of the carbon film is lower than about 100° C., the probability of forming a long polymer chain decreases. On the other hand, when the deposition temperature of the carbon film exceeds about 300° C., the hydrogen content may be rapidly reduced due to a bake-out phenomenon. When the deposition temperature of the carbon film is in a range of about 180 to 220° C., more specifically, about 200° C., the carbon film has the highest hydrogen content.

The deposition of the carbon film may be performed at a RF power of about 300 to 600 W. More preferably, the deposition of the carbon film may be performed at a RF power of about 350 to 450 W. When the RF power is lower than 300 W, the probability of forming a long polymer chain decreases. On the other hand, when the RF power exceeds about 600 W, the hydrogen content may rapidly decrease due to recombination after the destruction of the carbon precursor structure. When the RF power is in a range of about 350 to 450 W, more specifically, about 400 W, the carbon film has the highest hydrogen content.

The carbon film deposition may be preferably performed at a pressure of about 5 to 9 Torr. However, the present disclosure is not necessarily limited thereto.

The deposited carbon film may have a thickness of about 5 to 10 nm. However, the present disclosure is not necessarily limited thereto.

The hydrogen-containing carbon film deposition method according to the present disclosure as described above may achieve the high hydrogen content in the deposited carbon film through the substrate temperature control and the RF power control while using the single carbon precursor.

The carbon film having the high hydrogen content has good light transmittance. Thus, the carbon film may contribute to realizing an ultra-fine pattern of about 30 nm or smaller, which is essential in a semiconductor process.

In addition, when the carbon film auxiliary layer having a high hydrogen content is applied, the dose lower than the dose used conventionally may be used to contribute to energy reduction and productivity increase.

After the carbon film having a hydrogen content of about 40 atomic % or higher has been deposited using the PECVD apparatus using one type of the carbon precursor including carbon and hydrogen and having three or more carbon atoms in the process as described in FIG. 2, the carbon film may be additionally subjected to a post-plasma treatment.

A contact angle may be increased via the post-plasma treatment. The increase in the contact angle of the carbon film may improve adhesion to the photoresist pattern formed thereon.

The post-plasma treatment may be performed using hydrogen plasma or NF₃ plasma. However, when He plasma treatment is performed, the contact angle is lowered.

The deposition of the carbon film and the post-plasma treatment may be performed in an in-situ manner.

As described above, the deposited carbon film is subjected to the post-plasma treatment, thereby forming the hydrogen-containing carbon film having high adhesion to the photoresist pattern.

Therefore, the hydrogen-containing carbon film formed using the method according to the present disclosure has the high hydrogen content and a large contact angle, and thus is suitable for use as an auxiliary layer under a photoresist for an extreme ultraviolet process.

### EXAMPLES

Hereinafter, a configuration and an effect of the present disclosure will be described in more detail through preferred Examples of the present disclosure. However, this is presented as a preferred implementation of the present disclosure and cannot be interpreted as limiting the present disclosure in any sense.

The contents not described herein may be sufficiently technically inferred by those skilled in this technical field, and thus the description thereof will be omitted.

The carbon film was deposited under the process conditions as described in Table 1 as set forth below.

TABLE 1
Process condition

| | |
|---|---|
| Carbon precursor | C₃H₆, C₆H₁₂ |
| Carbon precursor flow rate | Approximately 500 sccm |
| Ar flow rate | Approximately 2000 |
| | sccm |
| Process pressure | Approximately 7 Torr |
| Substrate temperature | 100 to 300 degrees C. |
| RF power | 100 to 600 W |

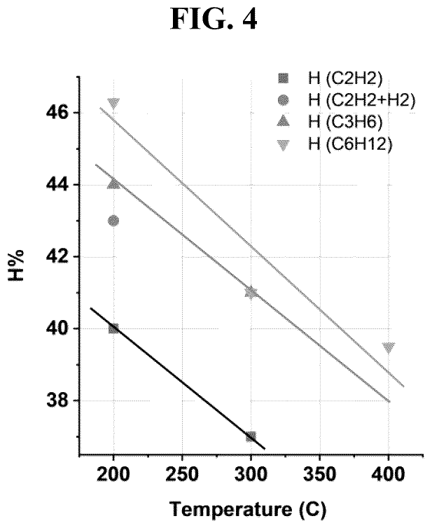

FIG. 4 is a graph showing a hydrogen content of a deposited carbon film based on a deposition source and a deposition temperature. In FIG. 4, the RF power was fixed at about 400 W.

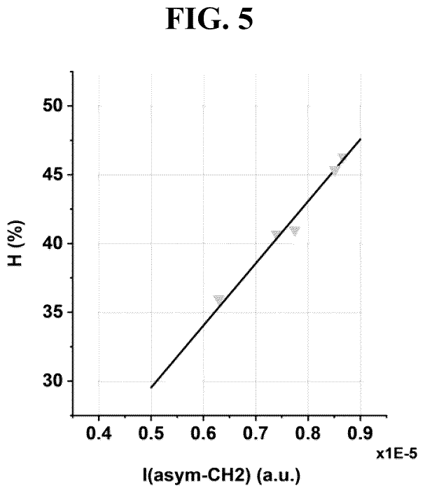

In FIG. 4, the hydrogen content (H atomic %) is a value converted from a FTIR result obtained from a graph showing the correlation between the FT-IR result of FIG. 5 and the hydrogen content in the carbon film.

Referring to FIG. 4, it may be identified that when C₃H₆ or C₆H₁₂ is used as the carbon precursor, the carbon film having a relatively high hydrogen content is deposited, in comparison to a case in which C₂H₂ is used as the carbon precursor, or a case in which C₂H₂ and H₂ are used together as the carbon precursor.

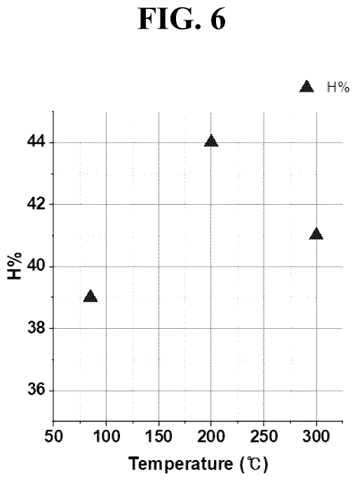

FIG. 6 shows the hydrogen content of the carbon film formed from C₃H₆ based on the substrate temperature. In FIG. 6, the RF power was fixed at about 400 W.

Referring to FIG. 6, the highest hydrogen content was obtained when the carbon film deposition was performed at a substrate temperature of about 200° C. The hydrogen content gradually decreased as the substrate temperature decreased therefrom or as the substrate temperature increased therefrom.

Accordingly, the deposition of the carbon film may be performed at a substrate temperature of about 100 to 300° C., and more preferably, may be performed at a substrate temperature of about 180 to 220° C.

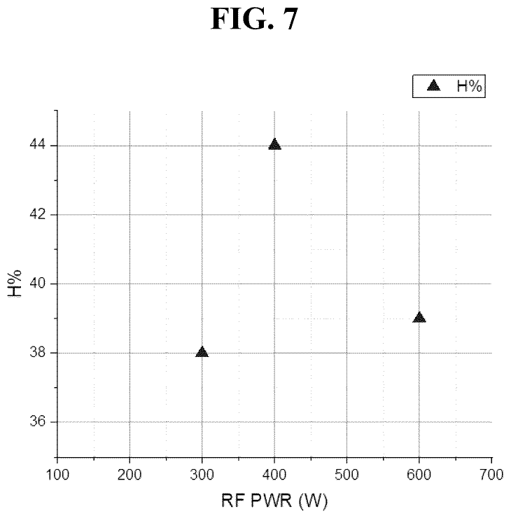

FIG. 7 shows the hydrogen content of the carbon film formed from C₃H₆ at about 200° C. based on the RF power.

Referring to FIG. 7, the highest hydrogen content was obtained when the carbon film deposition was performed at about 400 W of RF power. The hydrogen content gradually decreased as the RF power decreased therefrom or as the RF power increased therefrom.

Accordingly, the deposition of the carbon film may be performed at a RF power of about 300 to 600 W, and more preferably, may be performed at a RF power of about 350 to 450 W.

Table 2 as set forth below shows the contact angle of the carbon film when the carbon film is deposited under the process conditions of the substrate temperature about 200° C., and the RF power about 400 W, and when C₆H₁₂ is used alone as the carbon precursor. Further, the Table 2 shows the contact angle of the carbon film when the post-plasma treatment (PPT) is additionally performed on the deposited film.

TABLE 2

| | Immediately | | | |
|---|---|---|---|---|
| C₆H₁₂ | after deposition | H₂ PPT | He PPT | NF₃ PPT |
| Contact Angle (°) | 75 | 90 | 60 | 110 |

Referring to the Table 2, it may be identified that the contact angle increases when each of the post-plasma treatment (H₂ PPT) using hydrogen and the post-plasma treatment (NF₃ PPT) after nitrogen trifluoride are performed, compared to the contact angle immediately after the deposition. Such an increased contact angle may improve adhesion of the carbon film to the layer (e.g., a photoresist layer) formed on the carbon film.

However, when the post-plasma treatment (He PPT) using helium is performed, the contact angle is rather reduced. Therefore, it may be concluded that the post-plasma treatment is preferably performed using hydrogen plasma or NF₃ plasma.

Although the present disclosure has been described with reference to the accompanying drawings, the present disclosure is not limited by the embodiments disclosed herein and the drawings, and it is obvious that various modifications may be made by those skilled in the art within the scope of the technical idea of the present disclosure. In addition, although the effects based on the configuration of the present disclosure are not explicitly described and illustrated in the description of the embodiment of the present disclosure above, it is obvious that predictable effects from the configuration should also be recognized.

1. A method for forming a hydrogen-containing carbon film, the method comprising:
loading a substrate into a chamber;
supplying a carbon precursor into the chamber;
raising a temperature of the substrate to a predetermined temperature; and
discharging the carbon precursor in the chamber to deposit a carbon film on the substrate,
wherein the carbon precursor is one type of a compound including carbon and hydrogen and having 3 or more carbon atoms,
wherein a content of hydrogen contained in the deposited carbon film is about 40 atomic percent or higher.

2. The method for forming the hydrogen-containing carbon film of claim 1, wherein the carbon precursor is C₃H₆.

3. The method for forming the hydrogen-containing carbon film of claim 1, wherein the carbon precursor is C₆H₁₂.

4. The method for forming the hydrogen-containing carbon film of claim 1, wherein the carbon precursor together with a carrier gas are supplied into the chamber.

5. The method for forming the hydrogen-containing carbon film of claim 1, wherein the deposition of the carbon film is performed at a substrate temperature of about 100 to 300° C.

6. The method for forming the hydrogen-containing carbon film of claim 5, wherein the deposition of the carbon film is performed at a substrate temperature of about 180 to 220° C.

7. The method for forming the hydrogen-containing carbon film of claim 1, wherein the deposition of the carbon film is performed at a RF power of about 300 to 600 W.

8. The method for forming the hydrogen-containing carbon film of claim 7, wherein the deposition of the carbon film is performed at a RF power of about 350 to 450 W.

9. A method for forming a hydrogen-containing carbon film, the method comprising:
depositing a carbon film using a single type of a carbon precursor including carbon and hydrogen and having at least 3 carbon atoms in a PECVD process such that the deposited carbon film has a hydrogen content in a range of about 40 atomic % or greater; and
performing a post-plasma treatment on the deposited carbon film.

10. The method for forming the hydrogen-containing carbon film of claim 9, wherein the post-plasma treatment is performed using hydrogen plasma or NF₃ plasma.

11. The method for forming the hydrogen-containing carbon film of claim 9, wherein each of the deposition of the carbon film and the post-plasma treatment is performed in an in-situ manner.
